(19) United States
(12) Patent Application Publication
(10) Pub. No.: US 2013/0153004 A1
(43) Pub. Date: Jun. 20, 2013

(54) JUNCTION BOX WITH A SUPPORT MEMBER FOR THIN FILM PHOTOVOLTAIC DEVICES AND THEIR METHODS OF MANUFACTURE

(71) Applicants: Jeffrey Todd Knapp, Golden, CO (US); Max William Reed, Niwot, CO (US); Loucas Tsakalakos, Niskayuna, NY (US); Jeffrey Scott Erlbaum, Albany, NY (US)

(72) Inventors: Jeffrey Todd Knapp, Golden, CO (US); Max William Reed, Niwot, CO (US); Loucas Tsakalakos, Niskayuna, NY (US); Jeffrey Scott Erlbaum, Albany, NY (US)

(73) Assignee: PRIMESTAR SOLAR, INC., Arvada, CO (US)

(21) Appl. No.: 13/326,945

(22) Filed: Dec. 15, 2011

(51) Int. Cl. H01L 31/048; H01R 43/20

(52) U.S. Cl. 136/251; 29/876

(57) ABSTRACT

Photovoltaic devices are generally provided that can include, in one particular embodiment, a transparent substrate; a plurality of thin film layers defining a plurality of photovoltaic cells connected in series to each other on the transparent substrate; a first lead connected to one of the photovoltaic cells; and, an encapsulation substrate on the plurality of thin film layers. The encapsulation substrate can generally define a back surface and a connection aperture through which the first lead extends. A junction box can be positioned over the connection aperture and connected to the first lead. The junction box generally comprises a support member extending through the connection aperture to mechanically support the transparent substrate in an area opposite to the connection aperture. Methods and kits are also generally provided.

### FIELD OF THE INVENTION

The subject matter disclosed herein relates generally to photovoltaic devices including a junction box having a support beam positioned in a connection aperture of the encapsulating substrate to mechanically support the transparent substrate in the area of the connection aperture.

### BACKGROUND OF THE INVENTION

Thin film photovoltaic (PV) modules (also referred to as “solar panels”) based on cadmium telluride (CdTe) paired with cadmium sulfide (CdS) as the photo-reactive components are gaining wide acceptance and interest in the industry. CdTe is a semiconductor material having characteristics particularly suited for conversion of solar energy to electricity. The junction of the n-type layer (e.g., CdS) and the p-type layer (e.g., CdTe) is generally responsible for the generation of electric potential and electric current when the CdTe PV module is exposed to light energy, such as sunlight. A transparent conductive oxide (“TCO”) layer is commonly used between the window glass and the junction forming layers to serve as the front electrical contact on one side of the device. Conversely, a back contact layer is provided on the opposite side of the junction forming layers and is used as the opposite contact of the cell.

An encapsulation substrate is positioned on the opposite side of the device from the window glass to encase the thin film layers. The encapsulation substrate also serves to mechanically support the window glass of the PV device. However, the encapsulation substrate typically contains a hole that enables connection of the photovoltaic device to lead wires for the collection of the DC electricity created by the PV device. The presence of the hole in the encapsulation substrate can induce a weak point in the device. For example, the PV device may be particularly susceptible to impact damage (e.g., in the form of cracking) in the window glass in the area at or near the encapsulation hole, such as from a hail strike. This weakness can be exaggerated when the window glass is made from a specialty glass and/or a relatively thin glass.

As such, a need exists to inhibit and/or prevent cracking in the window glass of a PV device, particularly in the area where a hole is located in the encapsulation substrate.

### BRIEF DESCRIPTION OF THE INVENTION

Aspects and advantages of the invention will be set forth in part in the following description, or may be obvious from the description, or may be learned through practice of the invention.

Photovoltaic devices are generally provided that can include, in one particular embodiment, a transparent substrate; a plurality of thin film layers defining a plurality of photovoltaic cells connected in series to each other on the transparent substrate; a first lead connected to one of the photovoltaic cells; and, an encapsulation substrate on the plurality of thin film layers. The encapsulation substrate can generally define a back surface and a connection aperture through which the first lead extends. A junction box can be positioned over the connection aperture and connected to the first lead. The junction box generally comprises a support member extending through the connection aperture to mechanically support the transparent substrate in an area opposite to the connection aperture.

Kits are also generally provided for use with a photovoltaic device that has a first lead. In one embodiment, the kit can include an encapsulation substrate defining an aperture wall therein, where the aperture wall in turn defines a connection aperture having a perimeter defined by the aperture wall of the encapsulation substrate; and, a junction box configured to be attached to the encapsulation substrate over the connection aperture. The junction box generally includes a support member configured to extend through the connection aperture to mechanically support a transparent substrate in an area opposite to the connection aperture, and is configured such that when coupled with the photovoltaic device, the first lead is capable of extending through the connection aperture and be connected to the junction box.

Methods are also generally provided for supporting a transparent substrate in an area opposite from a connection aperture defined in an encapsulating substrate of a photovoltaic device that has a first lead. The method can include, in one embodiment, threading the first lead through the connection aperture; attaching the first lead to a junction box; and, attaching the junction box over the connection aperture such that a support member extending from the junction box is positioned to mechanically support the transparent substrate in the area opposite of the connection aperture.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 shows a general schematic of a cross-sectional view of an exemplary thin film photovoltaic device according to one embodiment;

FIG. 2 shows a perspective, cross-sectional view of an exemplary photovoltaic device for use with the junction box of any of FIGS. 3-9;

FIG. 3 shows a bottom perspective view of an exemplary junction box for use with the thin film photovoltaic devices of FIG. 1 or 2;

FIG. 4 shows a perspective, cross-sectional view of the exemplary junction box of FIG. 3;

FIG. 5 shows a bottom perspective view of another exemplary junction box for use with the thin film photovoltaic devices of FIG. 1 or 2;

FIG. 6 shows a bottom perspective view of yet another exemplary junction box for use with the thin film photovoltaic devices of FIG. 1 or 2;

FIG. 7 shows a bottom perspective view of yet another exemplary junction box for use with the thin film photovoltaic devices of FIG. 1 or 2;

FIG. 8 shows a bottom perspective view of yet another exemplary junction box for use with the thin film photovoltaic devices of FIG. 1 or 2; and,

FIG. 9 shows a bottom perspective view of yet another exemplary junction box for use with the thin film photovoltaic devices of FIG. 1 or 2.

Repeat use of reference characters in the present specification and drawings is intended to represent the same or analogous features or elements.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

In the present disclosure, when a layer is being described as “on” or “over” another layer or substrate, it is to be understood that the layers can either be directly contacting each other or have another layer or feature between the layers, unless otherwise specifically noted. Thus, these terms are simply describing the relative position of the layers to each other and do not necessarily mean “on top of” since the relative position above or below depends upon the orientation of the device to the viewer. Additionally, although the invention is not limited to any particular film thickness, the term “thin” describing any film layers of the photovoltaic device generally refers to the film layer having a thickness less than about 10 micrometers (“microns” or “μm”).

It is to be understood that the ranges and limits mentioned herein include all ranges located within the prescribed limits (i.e., subranges). For instance, a range from about 100 to about 200 also includes ranges from 110 to 150, 170 to 190, 153 to 162, and 145.3 to 149.6. Further, a limit of up to about 7 also includes a limit of up to about 5, up to 3, and up to about 4.5, as well as ranges within the limit, such as from about 1 to about 5, and from about 3.2 to about 6.5.

A thin film photovoltaic device is generally provided having a junction box with a built-in (e.g., integrally connected) support member positioned within a connection aperture of the encapsulation substrate (e.g., back glass) to mechanically support the transparent substrate (e.g., window glass) in the area of the connection aperture. The support member can be generally configured such that a first lead (and optionally a second lead) is able to extend through the connection aperture and electrically connect to the junction box, as desired, while the support member is in place within the connection aperture. As such, the support member can provide structural support and reinforcement for the transparent substrate while still enabling the connection aperture to be utilized to electrically connect the lead(s) of the PV device to the junction box.

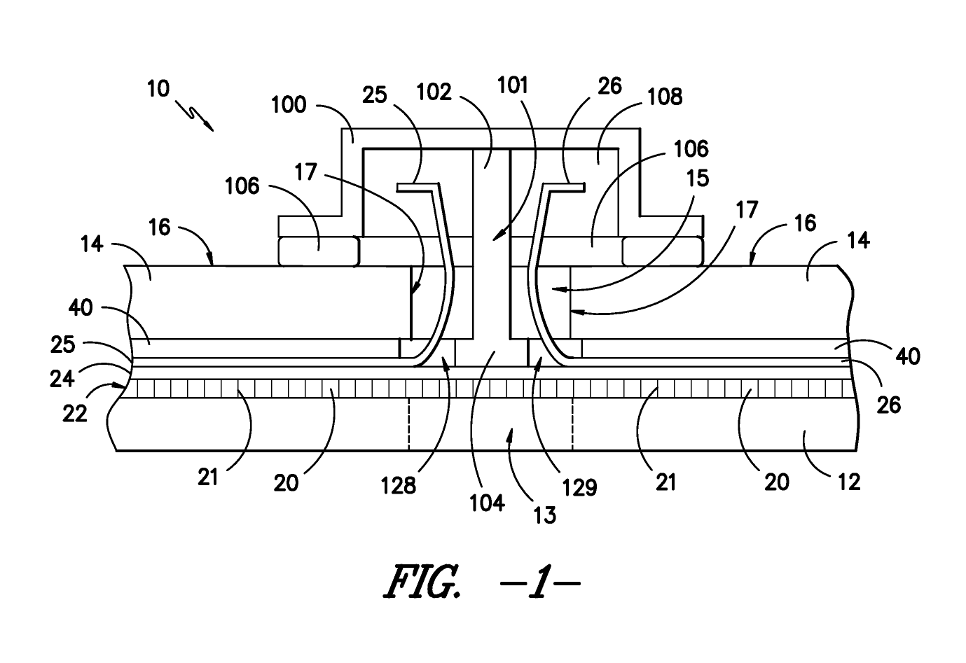

FIG. 1 shows a cross-sectional view of an exemplary thin film photovoltaic device 10 utilizing a junction box 100 having a support member 101 that extends from the housing 108. In the embodiment shown, the support member 101 includes a support beam 102 and a support insert 104 to mechanically support the transparent substrate 12 in an area 13 of the transparent substrate 12 that is opposite to the connection aperture 15 defined within the encapsulation substrate 14. Additionally, the support insert 104 is configured such that a first lead 25 and an optional second lead 26 are able to extend through the connection aperture 15 of the encapsulation substrate 14 while the support insert 104 is in place within the connection aperture 15. The first and second leads 25, 26 are generally configured to collect the DC current generated by the plurality of photovoltaic cells 20 in the device 10.

The support member 101 can be constructed from any suitable material that provides sufficient stiffness to mechanically support the transparent substrate 12 in the area 13 opposite to the connection aperture 15. For example, in certain embodiments, the support member 101 can be constructed from a molded plastic material, a molded hard rubber material, or a combination thereof.

As shown, the junction box 100 can be positioned (e.g., adhered) on the back surface 16 of the encapsulation substrate 14 over the connection aperture 15 such that the support member 101 extends through connection aperture 15 to mechanically support the transparent substrate 12 in the area 13 opposite to the connection aperture 15. For example, the support member 101 can contact a given layer (e.g., an underlying layer such as a back contact layer, insulation layer, etc.) on the transparent substrate 12. In one particular embodiment, the support member 101 can be adhered to the given layer on the transparent substrate 12.

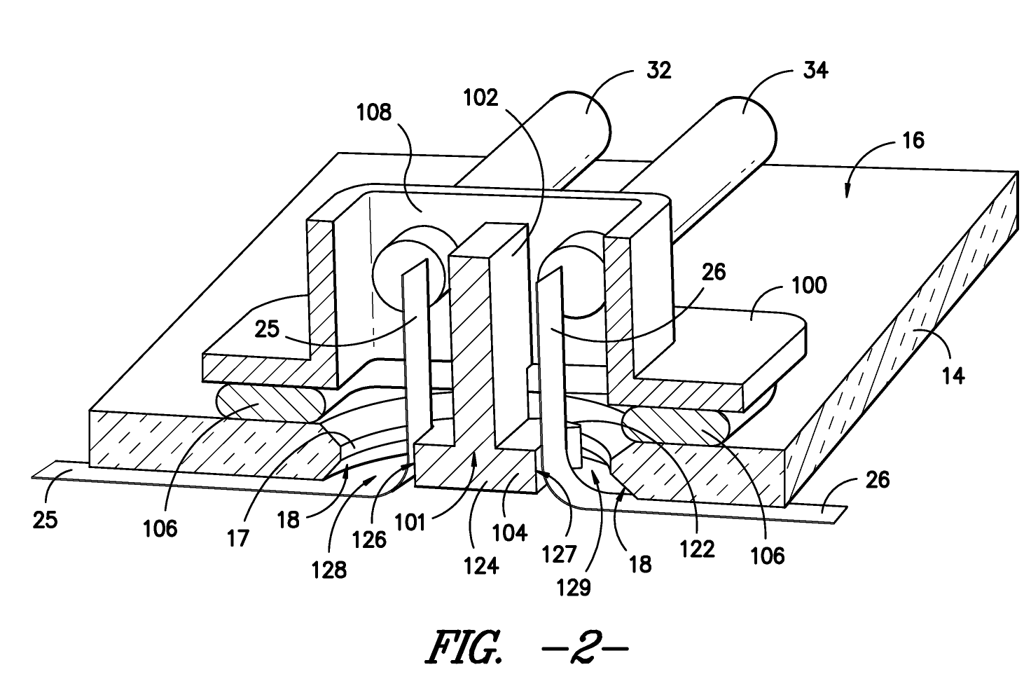

In one embodiment, the junction box 100 can be directly attached to the back surface 16 of the encapsulation substrate 14. Alternatively, the junction box 100 can be indirectly attached to the back surface 16, such as through a washer member as shown in FIGS. 1-2. The washer member 106 can be positioned on the back surface 16 of the encapsulation substrate 14 between the junction box 100 and the encapsulation substrate 14. For example, the washer member 106 can, in one embodiment, be perimetrically positioned about a perimeter of the connection aperture 15 and/or junction box 100. As such, the junction box 100 can be attached to the washer member 106 such that the junction box 100 is indirectly attached to the encapsulation substrate 14 through the washer member 106. The washer member 106 could, for example, be comprised of a gasket or a bead of adhesive, either of which would provide a degree of elastic “forgiveness” at the connection of the junction box 100 and the encapsulation substrate 14.

The support beam 102 of the support insert 101 can have any suitable design that can provide mechanical support to the area 13 of the transparent substrate 12 opposite to the connection aperture 15 in the encapsulation substrate 14. Likewise, the support insert 104 can have any suitable design for mechanically supporting the transparent substrate 12 in the area 13 opposite to the connection aperture 15 of the encapsulation substrate 14. In the embodiments shown, the connection aperture 15 generally has a circular shape, and likewise, the support insert 104 generally has a circular shape. However, it is understood that other shapes can be utilized as desired (e.g., square, oval, slot-like, etc.).

The connection aperture 15 can generally have a perimeter defined by an aperture wall 17 within the encapsulation substrate 14. In one embodiment, the aperture wall 17 can be coupled to the support insert 104. For instance, the aperture wall 17 can be beveled or chamfered, and the support insert 104 be configured to couple with the aperture wall 17. An adhesive can, in certain embodiments, be positioned to bond the support insert 104 to the aperture wall 17 of the encapsulation substrate 14 and/or to bond the support insert 104 to the underlying layers on the transparent substrate 12.

The support inserts 104 can have a variety of designs, and exemplary support inserts 104 are discussed in greater detail below. However, it is again noted that features of one embodiment may be combined with features of another embodiment to form an additional embodiment, even if not explicitly shown in the exemplary embodiments of the Figures.

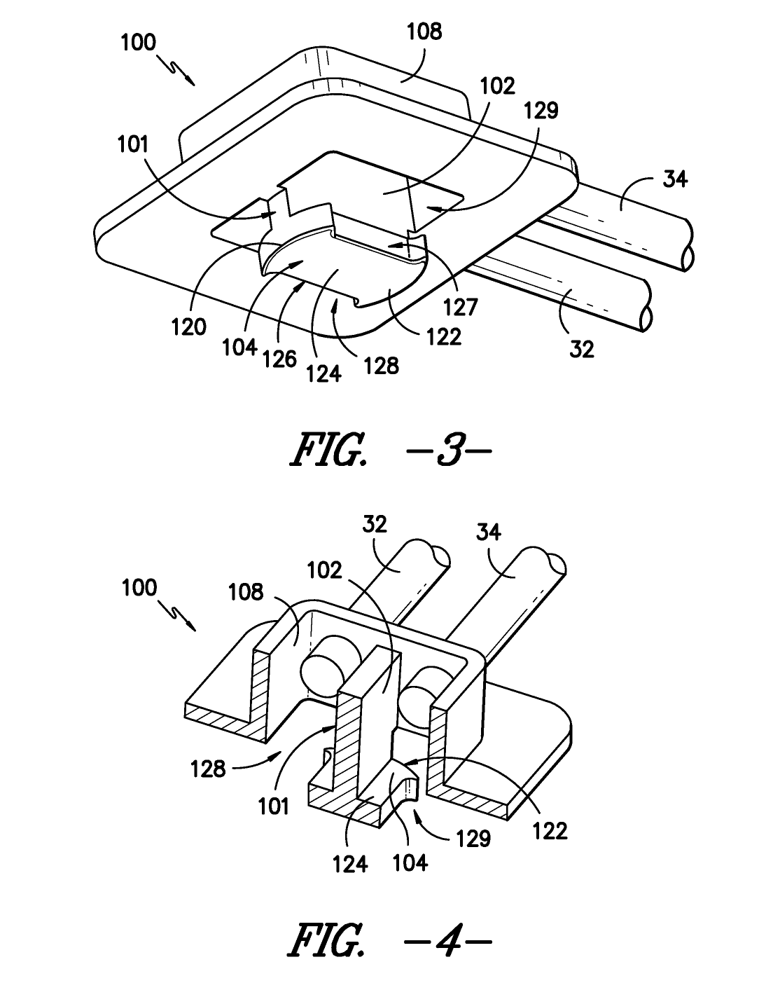

FIGS. 1-4 show an exemplary support insert 104 that defines two arc segments 120, 122 connected to each other via a midsection 124 that generally defines a first side 126 and a second side 127. The support insert 104 can be configured to define a first channel 128 between the first side 126 of the midsection 124 and the aperture wall 17 and a second channel 129 between the second side 127 and the connection aperture 15. As such, the first lead 25 can extend through the first channel 128, and the second lead 26 can extend though the second channel 129.

This configuration can substantially fill the connection aperture 15 to provide structural support throughout the area 13 of the transparent substrate 12. Additionally, this embodiment can allow for relatively easy insertion of the support insert 104 into the connection aperture 15 without threading of the leads 25, 26 into a slot or slots. For example, the leads 25, 26 can be inserted through the connection aperture 15 and wrapped back onto the back surface 16 of the encapsulation substrate 14. Then, the support insert 104 can be inserted into the connection aperture 15 and positioned such that the first channel 128, formed between the first side 126 of the midsection 124 and the aperture wall 17, is located where the first lead 25 is already situated, and the second channel 129, formed between the second side 127 and the connection aperture 15, is located where the second lead 26 is already situated.

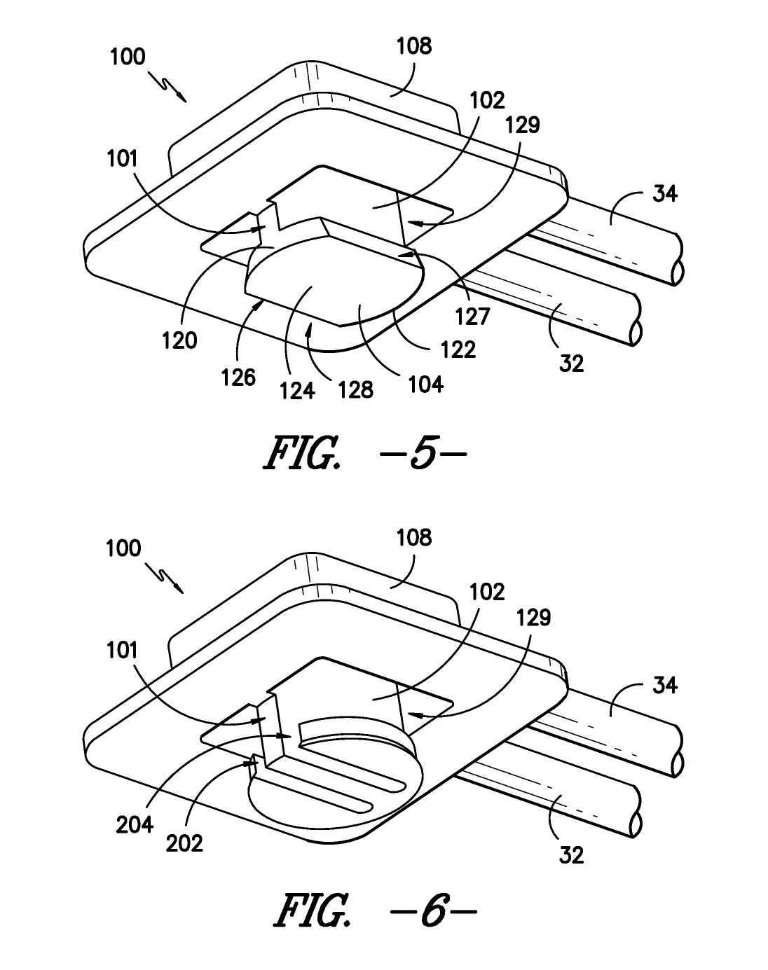

The support insert 104 can be configured such that the channels 128, 129 are sized according to the size of the leads 25, 26, respectively. For example, the embodiments of FIGS. 1-4 show that the two arc segments 120, 122 extend beyond the width of the midsection 124. However, the embodiment of FIG. 5 shows that the midsection 124 has substantially the same width as the two arc segments 120, 122. Otherwise, the embodiment of FIG. 5 is substantially similar to that of FIGS. 1-4 discussed above.

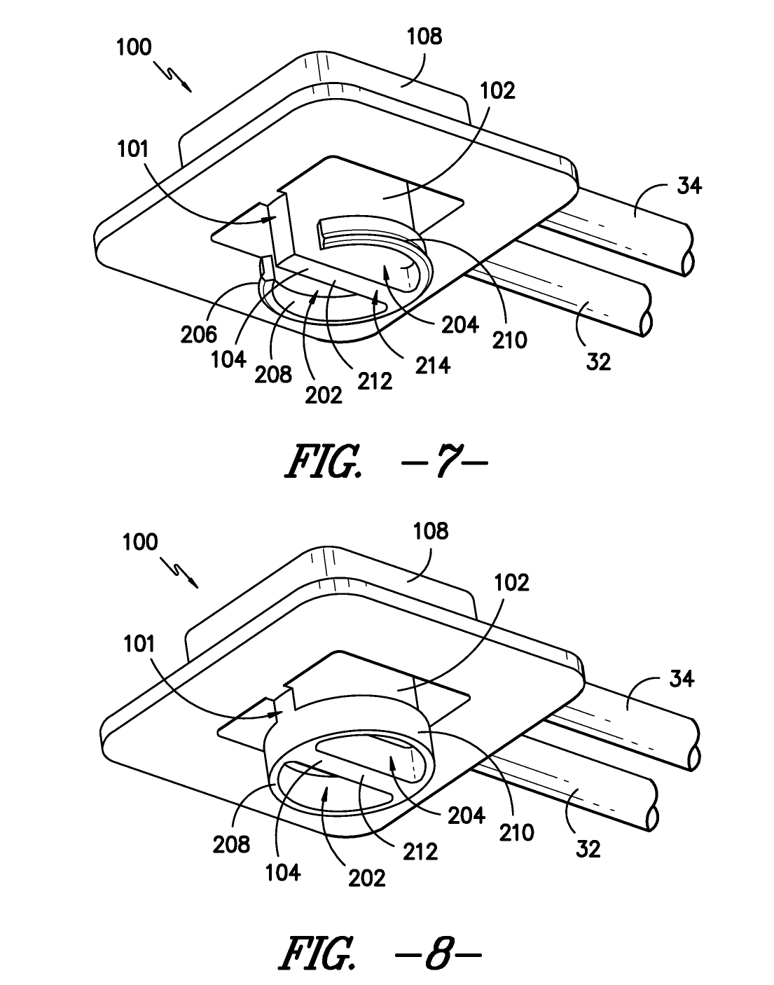

Referring to FIGS. 6-7, the support insert 104 can define a first slot 202 and a second slot 204 that allow, respectively, the first lead 25 and the second lead 26 to extend therethrough. As shown, the first slot 202 and the second slot 204 are open-ended in the support insert 104, which can allow the first lead 25 and the second lead 26 to be pulled into their respective slots 202, 204 without threading.

In the embodiment of FIGS. 6-7, the support insert 104 also defines a lip 206 configured to couple with a groove 18 defined in the aperture wall 17 of the encapsulation substrate 14. The first and second slots 202, 204 can, in this configuration, not only provide access for the first and second leads 25, 26, respectively, but also can provide flexibility in its circumference to allow for the insertion of the support insert 104 into the connection aperture 15 even with the lip 206 being present and being slightly larger (in diameter) than the smallest diameter of the connection aperture 15.

Referring to the embodiment of FIG. 7, the support insert 104 defines a first exterior beam 208, a second exterior beam 210, and an interior beam 212 that are connected to each other at a location 214. The interior beam 212 can extend between the first exterior beam 208 and the second exterior beam 210 such that the first slot 202 is defined between the first exterior beam 208 and the interior beam 212, while the second slot 204 is defined between the second exterior beam 210 and the interior beam 212.

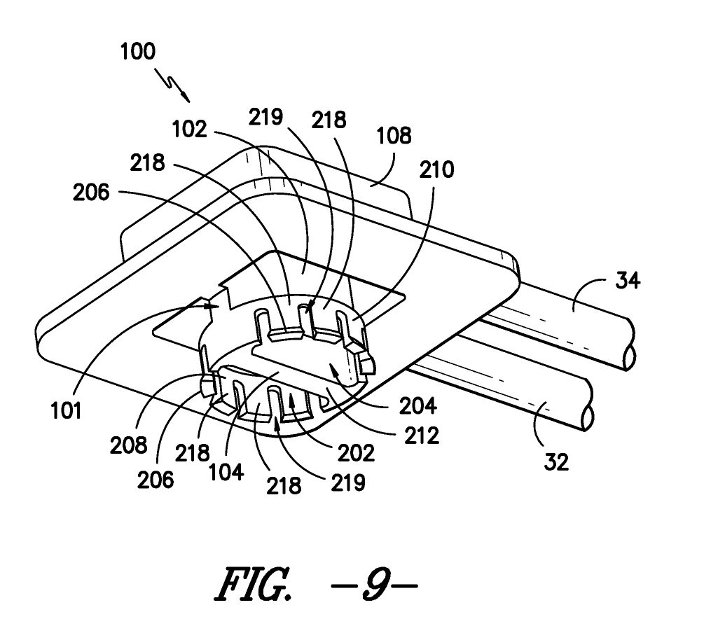

FIGS. 8-9 show an embodiment of the support insert 104 that defines a first slot 202 and a second slot 204 that are closed-ended. That is, while the first slot 202 and second slot 204 allow, respectively, for the first lead 25 and the second lead 26 to extend therethrough, the first slot 202 and the second slot 204 are closed-ended such that the first lead 25 and the second lead 26 can be threaded into and through the respective slots 202, 204. Such an embodiment can provide additional stiffness to the support insert 104 by removing any flexibility due to open-ended slots.

The support insert 104 defines a first exterior beam 208, a second exterior beam 210, and an interior beam 212 that are connected to each other at a first location 214 and a second location 216 with the interior beam 212 extending between the first exterior beam 208 and the second exterior beam 210. By being connected in this manner, the first slot 202 is defined between the first exterior beam 208 and the interior beam 212 and the second slot 204 is defined between the second exterior beam 210 and the interior beam 212. Thus, the first and second slots 202, 204 are closed-ended to provide support to the transparent substrate 12 around the entire circumference of the area 13 and through the middle of the area 13.

The embodiments of FIG. 8 defines a substantially straight surface (i.e., without a lip) and can be particularly useful with encapsulation substrate 14 that define an aperture wall 17 completely oriented in the z-direction D_{z} (i.e., without a groove).

In the embodiment shown in FIG. 9, the support insert 104 defines a lip 206 on tabs 218. The tabs 218 are generally configured to extend into the connection aperture 15 and to couple with a groove 18 in the aperture wall 17. The tabs 218 are separated from one another by the corresponding spacer slots 219 to allow flexibility to the tabs 218 such that the support insert 104 can be “snapped” into the connection aperture 15 that defines a groove 18 in the aperture wall 17.

Referring again to FIG. 1, the transparent substrate 12 can be, in one embodiment, a “superstrate,” as it can be the substrate on which the subsequent layers are formed even though it faces upward to the radiation source (e.g., the sun) when the photovoltaic device 10 is in use. The transparent substrate 12 can be a high-transmission glass (e.g., high transmission borosilicate glass), low-iron float glass, or other highly transparent glass material. The glass is generally thick enough (e.g., from about 0.5 mm to about 10 mm thick) to provide support for the subsequent film layers, and is substantially flat to provide a good surface for forming the subsequent film layers. In one embodiment, the glass 12 can be a low iron float glass containing less than about 0.015% by weight iron (Fe), and may have a transmissiveness of about 0.9 or greater in the spectrum of interest (e.g., wavelengths from about 300 nm to about 900 nm). In another embodiment, a high strain-point glass, such as borosilicate glass, may be utilized so as to better withstand high temperature processing. For example, the transparent substrate 12 can be a relatively thin sheet of borosilicate glass, such as having a thickness of about 0.5 mm to about 2.5 mm.

The encapsulation substrate 14 defines a connection aperture 15 providing access to the underlying components to collect the DC electricity generated by the photovoltaic device 10. In one particular embodiment, the encapsulation substrate 14 is a glass substrate, such as those discussed above with respect to the transparent substrate 12. For example, in one embodiment, the transparent substrate 12 can be a borosilicate glass having a thickness of about 0.5 mm to about 2.5 mm, while the encapsulation substrate 14 is a low iron float glass having a thickness that is greater than that of the transparent substrate 12 (e.g., about 3 mm to about 10 mm).

The thin film stack 22 in the device 10 can include a plurality of thin film layers positioned on the transparent substrate 12. The thin film stack can define individual photovoltaic cells 20 separated by scribe lines 21. The individual photovoltaic cells 20 are electrically connected together in series. In one particular embodiment, the thin film stack 22 can include a transparent conductive oxide layer (e.g., cadmium stannate or a stoichiometric variation of cadmium, tin, and oxygen; indium tin oxide, etc.) on the transparent substrate 12, an optional resistive transparent buffer layer (e.g., a combination of zinc oxide and tin oxide, etc.) on the transparent conductive oxide layer, an n-type window layer on the resistive transparent buffer layer, an absorber layer on the n-type window layer, and a back contact on the absorber layer. In one particular embodiment, the n-type window layer can include cadmium sulfide (i.e., a cadmium sulfide thin film layer), and/or the absorber layer can include cadmium telluride (i.e., a cadmium telluride thin film layer). Other thin film layers may also be present in the film stack, as desired. Generally, the back contact defines the exposed surface of the thin film stack 22, and serves as an electrical contact of the thin film layers opposite the front contact defined by the transparent conductive oxide layer.

An insulating layer 24 is provided on the thin film stack 22 to isolate the back contact of the thin film stack 22 from the leads 25, 26. The insulating layer 24 generally includes an insulating material that can prevent electrical conductivity therethrough. Any suitable material can be used to produce the insulating layer 24. In one embodiment, the insulating layer 24 can be an insulating polymeric film coated on both surfaces with an adhesive coating. The adhesive coating can allow for adhesion of the insulating layer 24 to the underlying thin film stack 22 and for the adhesion of the leads 25, 26 to the insulating layer 24. For example, the insulating layer 24 can include a polymeric film of polyethylene terephthalate (PET) having an adhesive coating on either surface. The adhesive coating can be, for example, an acrylic adhesive, such as a pressure sensitive acrylic adhesive.

In one particular embodiment, the insulating layer 24 is a strip of insulating material generally oriented in a direction perpendicular to the orientation of the scribe lines 21. The insulating layer 24 can have a thickness in the z-direction suitable to prevent electrical conductivity from the underlying thin film stack 22, particularly the back contact, to any subsequently applied layers. In one particular embodiment, the insulating layer 24 can prevent electrically conductivity between the thin film stack 22 and the leads 25, 26.

Optionally, an intra-laminate disk layer (not shown) can be positioned on the insulating layer 24 over an area of the thin film stack 22 to be exposed by the connection aperture 15 of the encapsulation substrate 14 to act as a moisture barrier. For example, the intra-laminate disk layer can extend over a protected area that equal to or larger than the connection aperture 15 defined by the encapsulation substrate 14.

When present, the intra-laminate disk layer can define a substantially circular disk in the x, y plane (which is perpendicular to the z-direction D_{z}). This shape can be particularly useful when the connection aperture 15 in the encapsulation substrate 14 has the same shape in the x, y plane (e.g., circular). As such, the intra-laminate disk layer can be substantially centered with respect to the connection aperture 15 defined by the encapsulation substrate 14. Also, with this configuration, the disk diameter of the intra-laminate disk layer can be larger than the aperture diameter defined by the connection aperture 15. For instance, the disk diameter can be at about 5% larger to about 200% larger than the connection diameter, such as about 10% larger to about 100% larger. However, other sizes and shapes may be used as desired. In certain embodiments, the intra-laminate disk layer can define a thickness, in the z-direction, of about 50 μm to about 400 μm. If too thick, however, the intra-laminate disk layer could lead to de-lamination of the device 10.

The intra-laminate disk layer can, in one embodiment, be a polymeric film. In one particular embodiment, the film can be a polymeric film, including polymers such as polyethylene, polypropylene, polyethylene terephthalate (PET), ethylene-vinyl acetate copolymer, or copolymers or mixtures thereof. Alternatively, the intra-laminate disk layer can be a sheet of thin glass, e.g., having a thickness of about 0.02 mm to about 0.25 mm (e.g., 0.04 mm to 0.15 mm). When constructed of glass, the intra-laminate disk layer can provide excellent barrier properties to moisture along with providing some structural support to the device 10. It is to be understood that the intra-laminate disk layer could yet instead be in the form of a laminated glass disk, with a glass sheet having a laminate layer thereon being made, for example, of a polymeric film as per above. Such a laminated glass disk could provide the adhesion characteristics of the polymeric film and the barrier properties of the glass, and may also play a role in making the hole region more resistant to hail impact, especially if it is comprised of glass.

In one embodiment, for example, the intra-laminate disk layer can be constructed of a film having a polymeric coating on one or both surfaces. The polymeric coating can include a hydrophobic polymer configured to inhibit moisture ingress through the intra-laminate disk layer and/or around the intra-laminate disk layer. In addition, the polymeric coating can help adhere the intra-laminate disk layer to the underlying layers (e.g., the thin film stack 22) and subsequently applied layers (e.g., the adhesive layer 40). In one particular embodiment, the polymeric coating can include a material similar to the adhesive layer 40 employed in the device (e.g., an ethylene-vinyl acetate copolymer).

A sealing layer (not shown) can also be applied on the thin film stack 22 and the insulating layer 24 (and the optional intra-laminate disk layer, if present). When both the sealing layer and the intra-laminate disk layer are present, the sealing layer can help to hold the intra-laminate disk layer in place in the finished PV device 10 by providing the intra-laminate disk in a smaller size in the x, y plane (e.g., a smaller diameter) than the sealing layer, such that the sealing layer bonds the edges of the intra-laminate disk layer to the thin film stack 22.

Whether or not the intra-laminate disk layer, is present, the sealing layer can be positioned where the connection aperture 15 of the encapsulation substrate 14 is located on the device 10. The composition of the sealing layer (e.g., a synthetic polymeric material, as discussed below) can be selected such that the sealing layer has a moisture vapor transmission rate that is 0.5 g/m²/24 hr or less (e.g., 0.1 g/m²/24 hr or less, such as 0.1 g/m²/24 hr to about 0.001 g/m²/24 hr). As used herein, the “moisture vapor transmission rate” is determined according to the test method of ASTM F1249 at a 0.080″ thickness. As such, the sealing layer can form a moisture barrier between the connection aperture 15 in the encapsulation substrate 14 and the thin film stack 22 and define a protected area thereon.

In one embodiment, the sealing layer can be sized to be larger than the connection aperture 15 defined by the encapsulation substrate 14 (e.g., if circular, the sealing layer can have a diameter that is larger than the diameter of the connection aperture 15). In this embodiment, the sealing layer can not only form a moisture barrier between the protected area of the thin film stack 22 and the connection aperture 15, but also can help adhere the encapsulation substrate 14 to the underlying layers of the device 10.

In one particular embodiment, the sealing layer can include a synthetic polymeric material. The synthetic polymeric material can, in one embodiment, melt at the lamination temperature, reached when the encapsulation substrate 14 is laminated to the substrate 12, such that the synthetic polymeric material melts and/or otherwise conforms and adheres to form a protected area on the thin film stack 22 where the connection aperture 15 is located on the device 10. For instance, the synthetic polymeric material can melt at laminations temperatures of about 120° C. to about 160° C.

The synthetic polymeric material can be selected for its moisture barrier properties and its adhesion characteristics, especially between the encapsulation substrate 14 (e.g., a glass) and the back contact layer(s) of the thin film stack 22. For example, the synthetic polymeric material can include, but is not limited to, a butyl rubber or other rubber material. Though the exact chemistry of the butyl rubber can be tweaked as desired, most butyl rubbers are a copolymer of isobutylene with isoprene (e.g. produced by polymerization of about 98% of isobutylene with about 2% of isoprene). One particularly suitable synthetic polymeric material for use in the sealing layer is available commercially under the name HelioSeal® PVS 101 from ADCO Products, Inc. (Michigan Center, Mich.).

The leads 25, 26, in one embodiment, can be applied as a continuous strip over the insulating layer 24 and the optional sealing layer, and then the continuous strip can then be severed to produce the first lead 25 and the second lead 26, as shown in FIG. 1. The leads 25, 26 can be constructed from any suitable material. In one particular embodiment, the leads 25, 26 are formed from a strip of metal foil. For example, the metal foil can include a conductive metal.

Sealing strips (not shown) can extend over a portion of the first lead 25 and the second lead 26, respectively. The sealing strips may be connected to each other, such as in the form of a ring. No matter their exact configuration, the sealing layer can be thermally bonded to the first sealing strip and the second sealing strip to surround the first lead 25 and second lead 26, respectively. Thus, the first sealing strip and the sealing layer can form a circumferential moisture barrier about the first lead 25 to inhibit moisture ingress along the first lead 25 and into the device 10. Likewise, the second sealing strip and the sealing layer can form a circumferential moisture barrier about the second lead 26 to inhibit moisture ingress along the second lead 26 and into the device 10.

The sealing strips can have any composition as discussed above with respect to the sealing layer. Although the composition of the sealing strips may be selected independently from the each other and/or the sealing layer, in one embodiment, the sealing strips can have the same composition as the sealing layer (e.g., a butyl rubber).

The encapsulation substrate 14 can be adhered to the photovoltaic device 10 via an adhesive layer 40 and, if present, the sealing layer and the sealing strips (or ring). The adhesive layer 40 can be generally positioned over the leads 25, 26, insulating layer 24, and any remaining exposed areas of the thin film stack 22. The adhesive layer 40 can generally define an adhesive gap that generally corresponds to the connection aperture 15 defined by the encapsulation substrate 14. As such, the first lead 25 and second lead 26 can extend through the adhesive gap. The adhesive layer 40 can generally protect the thin film stack 22 and attach the encapsulation substrate 14 to the underlying layers of the device 10. The adhesive layer can be constructed from, for example, ethylene vinyl acetate (EVA), polyvinyl butyral (PVB), silicone based adhesives, or other adhesives which are configured to prevent moisture from penetrating the device.

Finally, the junction box 100 can be attached to the device 10 and positioned to cover the connection aperture 15, such as shown in FIGS. 1-2 and discussed above. The junction box 100 can be configured to electrically connect the photovoltaic device 10 by completing the DC circuit and provide a positive lead wire 32 and a negative lead wire 34 for further collection of the DC electricity produced by the photovoltaic device 10.

Other components and features (not shown) can be included in the exemplary device 10, such as bus bars, external wiring, laser etches, etc. For example, edge sealing layers can be applied around the edges of the device 10 to seal the substrate 12 to the encapsulation substrate 14 along each edge. Additionally, bus bars (not shown) can be attached to connect the photovoltaic cells 20 of the thin film stack 22 to the first lead 25 and second lead 26. Since the photovoltaic cells 20 are connected to each other in series, the bus bars can serve as opposite electrical connections (e.g., positive and negative) on the photovoltaic device 10.

Methods of manufacturing the devices 10 of FIGS. 1 and 2 and the support inserts 104 of FIGS. 3-9 are also encompassed by the present disclosure. Additionally, methods are provided for positioning the junction boxes 100 of FIGS. 1-9 onto a photovoltaic device 10.

In one embodiment, for example, a method is generally provided for supporting a transparent substrate in an area opposite from a connection aperture defined in an encapsulating substrate of a photovoltaic device that has a first lead. The method can generally include threading the first lead through the connection aperture; attaching the first lead to a junction box; and, attaching the junction box over the connection aperture such that a support member extending from the junction box is positioned to mechanically support the transparent substrate in the area opposite of the connection aperture.

Kits are also disclosed that generally include a junction box having a support member (e.g., any of the junction boxes 100 of FIGS. 1-9), an encapsulation substrate defining a connection aperture, optionally a washer member, and optionally other components of the devices 10 of FIGS. 1 and 2. For example, the kit for use with a photovoltaic device can include an encapsulation substrate defining a connection aperture having a perimeter defined by an aperture wall of the encapsulation substrate and a junction box configured to be attached to the encapsulation substrate over the connection aperture, wherein the junction box comprises a support member configured to extend through the connection aperture to mechanically support a transparent substrate in an area opposite to the connection aperture. The junction box can be configured such that when coupled with the photovoltaic device, the first lead is capable of extending through the connection aperture to be connected to the junction box. In one embodiment, the kit can further include a washer member configured to be positioned around the connection aperture and between the encapsulation substrate and the junction box such that the junction box is indirectly attached to the encapsulation substrate via the washer member.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A photovoltaic device, comprising:
a transparent substrate;
a plurality of thin film layers on the transparent substrate, wherein the plurality of thin film layers define a plurality of photovoltaic cells connected in series to each other;
a first lead connected to one of the photovoltaic cells;
an encapsulation substrate on the plurality of thin film layers, wherein the encapsulation substrate defines a back surface and a connection aperture through which the first lead extends; and,
a junction box positioned over the connection aperture and connected to the first lead, wherein the junction box comprises a support member extending through the connection aperture to mechanically support the transparent substrate in an area opposite to the connection aperture.

2. The photovoltaic device as in claim 1, wherein the junction box is adhered to the back surface of the encapsulation substrate.

3. The photovoltaic device as in claim 1, wherein the support member contacts a given layer on the transparent substrate.

4. The photovoltaic device as in claim 3, wherein the support member is adhered to the given layer on the transparent substrate.

5. The photovoltaic device as in claim 1, further comprising:
a washer member positioned perimetrically on the back surface of the encapsulation substrate about a perimeter of the connection aperture, the washer member serving as an interface between the junction box and the encapsulation substrate.

6. The photovoltaic device as in claim 5, wherein the junction box is attached to the washer member.

7. The photovoltaic device as in claim 1, wherein the support member comprises a support insert attached to a support beam, wherein the support insert contacts a given layer on the transparent substrate.

8. The photovoltaic device as in claim 7, wherein the support insert defines a first slot, wherein the first lead extends through the first slot.

9. The photovoltaic device as in claim 1, further comprising:
a second lead connected to another one of the photovoltaic cells, wherein the second lead extends through the connection aperture defined in the encapsulation substrate.

10. The photovoltaic device as in claim 9, wherein the support insert defines two circular segments connected to each other via a midsection, the midsection defining a first side and a second side.

11. The photovoltaic device as in claim 10, wherein the midsection is configured to define a first channel between the first side and a first one of the two circular segments with the first lead extending therethough, and wherein the midsection is configured to define a second channel between the second side and a second one of the two circular segments with the second lead extending therethough.

12. The photovoltaic device as in claim 9, wherein the support insert defines a first slot and a second slot, wherein the first lead extends through the first slot and the second lead extends through the second slot.

13. The photovoltaic device as in claim 12, wherein the first slot and the second slot are open-ended in the support insert.

14. The photovoltaic device as in claim 12, wherein the support insert defines a first exterior beam, a second exterior beam, and an interior beam, wherein the first exterior beam, the second exterior beam, and the interior beam are connected to each other at a first location with the interior beam extending between the first exterior beam and the second exterior beam such that the first slot is defined between the first exterior beam and the interior beam and the second slot is defined between the second exterior beam and the interior beam.

15. The photovoltaic device as in claim 14, wherein the first exterior beam, the second exterior beam, and the interior beam are further connected to each other at a second location such that the first slot and the second slot are closed-ended in the support insert.

16. The photovoltaic device as in claim 14, wherein the first exterior beam, the second exterior beam, and the interior beam are connected to each other only at the first location such that the first slot and the second slot are open-ended in the support insert.

17. A kit for use with a photovoltaic device that has a first lead, the kit comprising:
an encapsulation substrate defining an aperture wall therein, the aperture wall defining a connection aperture having a perimeter defined by the aperture wall of the encapsulation substrate; and,
a junction box configured to be attached to the encapsulation substrate over the connection aperture, wherein the junction box comprises a support member configured to extend through the connection aperture to mechanically support a transparent substrate in an area opposite to the connection aperture, and wherein the junction box is configured such that when coupled with the photovoltaic device, the first lead is capable of extending through the connection aperture and be connected to the junction box.

18. The kit as in claim 17, wherein the support insert defines two circular segments connected to each other via a midsection, the midsection defining a first side and a second side.

19. The kit as in claim 17, further comprising:
a washer member configured to be positioned around the connection aperture and between the encapsulation substrate and the junction box such that the junction box is indirectly attached to the encapsulation substrate via the washer member.

20. A method of supporting a transparent substrate in an area opposite from a connection aperture defined in an encapsulating substrate of a photovoltaic device that has a first lead, the method comprising:
threading the first lead through the connection aperture;
attaching the first lead to a junction box; and,
attaching the junction box over the connection aperture such that a support member extending from the junction box is positioned to mechanically support the transparent substrate in the area opposite of the connection aperture.
